(19) United States
(12) Patent Application Publication
(10) Pub. No.: US 2019/0295880 A1
(43) Pub. Date: Sep. 26, 2019

(54) CHEMICAL VAPOR DEPOSITION WAFER CARRIER WITH THERMAL COVER

(71) Applicant: Veeco Instruments Inc., Plainview, NY (US)

(72) Inventors: Sandeep Krishnan, Jersey City, NJ (US); Yuliy Rashkovsky, Millburn, NJ (US); Alexander Gurary, Bridgewater, NJ (US); Leo Chin, Poughquag, NY (US); Mandar Deshpande, Bridgewater, NJ (US)

(21) Appl. No.: 15/936,023

(22) Filed: Mar. 26, 2018

(51) Int. Cl. H01L 21/687; C23C 16/458

(52) U.S. Cl. CPC H01L 21/68785; H01L 21/68771; C23C 16/4584

(57) ABSTRACT

A wafer carrier as described and claimed herein includes a thermal cover and a plurality of platforms with corresponding radially inner and outer pedestals.

### TECHNICAL FIELD

The invention relates generally to semiconductor fabrication technology and, more particularly, to chemical vapor deposition (CVD) processing and associated apparatus, for holding semiconductor wafers during processing.

### BACKGROUND

In the fabrication of light-emitting diodes (LEDs) and other high-performance devices such as laser diodes, optical detectors, and field effect transistors, a chemical vapor deposition (CVD) process is typically used to grow a thin film stack structure using materials such as gallium nitride over a sapphire or silicon substrate. A CVD tool includes a process chamber, which is a sealed environment that allows infused gases to react upon the substrate (typically in the form of wafers) to grow the thin film layers. Examples of current product lines of such manufacturing equipment are the TurboDisc® and EPIK® families of metal organic chemical vapor deposition (MOCVD) systems, manufactured by Veeco Instruments Inc. of Plainview, N.Y.

A number of process parameters are controlled, such as temperature, pressure and gas flow rate, to achieve a desired crystal growth. Different layers are grown using varying materials and process parameters. For example, devices formed from compound semiconductors such as III-V semiconductors typically are formed by growing successive layers of the compound semiconductor using MOCVD. In this process, the wafers are exposed to a combination of gases, typically including a metal organic compound as a source of a group III metal, and also including a source of a group V element which flow over the surface of the wafer while the wafer is maintained at an elevated temperature. Generally, the metal organic compound and group V source are combined with a carrier gas which does not participate appreciably in the reaction as, for example, nitrogen. One example of a III-V semiconductor is gallium nitride, which can be formed by reaction of an organo-gallium compound and ammonia on a substrate having a suitable crystal lattice spacing, as for example, a sapphire wafer. The wafer is usually maintained at a temperature on the order of 1000-1100° C. during deposition of gallium nitride and related compounds.

In a MOCVD process, where the growth of crystals occurs by chemical reaction on the surface of the substrate, the process parameters must be controlled with particular care to ensure that the chemical reaction proceeds under the required conditions. Even small variations in process conditions can adversely affect device quality and production yield. For instance, if a gallium and indium nitride layer is deposited, variations in wafer surface temperature will cause variations in the composition and bandgap of the deposited layer. Because indium has a relatively high vapor pressure, the deposited layer will have a lower proportion of indium and a greater bandgap in those regions of the wafer where the surface temperature is higher. If the deposited layer is an active, light-emitting layer of an LED structure, the emission wavelength of the LEDs formed from the wafer will also vary to an unacceptable degree.

In a MOCVD process chamber, semiconductor wafers on which layers of thin film are to be grown are placed on rapidly-rotating carousels, referred to as wafer carriers, to provide a uniform exposure of their surfaces to the atmosphere within the reactor chamber for the deposition of the semiconductor materials. Rotation speed is on the order of 1,000 RPM. The wafer carriers are typically machined out of a highly thermally conductive material such as graphite, and are often coated with a protective layer of a material such as silicon carbide. Each wafer carrier has a set of circular indentations, or pockets, in its top surface in which individual wafers are placed. Typically, the wafers are supported in spaced relationship to the bottom surface of each of the pockets to permit the flow of gas around the edges of the wafer. Some examples of pertinent technology are described in U.S. Patent Application Publication No. 2012/0040097, U.S. Pat. Nos. 8,092,599, 8,021,487, U.S. Patent Application Publication No. 2007/0186853, U.S. Pat. Nos. 6,902,623, 6,506,252, and 6,492,625, the disclosures of which are incorporated by reference herein.

The wafer carrier is supported on a spindle within the reaction chamber so that the top surface of the wafer carrier having the exposed surfaces of the wafers faces upwardly toward a gas distribution device. While the spindle is rotated, the gas is directed downwardly onto the top surface of the wafer carrier and flows across the top surface toward the periphery of the wafer carrier. The used gas is evacuated from the reaction chamber through ports disposed below the wafer carrier. The wafer carrier is maintained at the desired elevated temperature by heating elements, typically electrical resistive heating elements disposed below bottom surface of the wafer carrier. These heating elements are maintained at a temperature above the desired temperature of the wafer surfaces, whereas the gas distribution device typically is maintained at a temperature well below the desired reaction temperature so as to prevent premature reaction of the gases. Therefore, heat is transferred from the heating elements to the bottom surface of the wafer carrier and flows upwardly through the wafer carrier to the individual wafers.

The gas flow over the wafers varies depending on the radial position of each wafer, with outermost-positioned wafers being subjected to higher flow rates due to their faster velocity during rotation. Even on each individual wafer there can be temperature non-uniformities, i.e., cold spots and hot spots. One of the variables affecting the formation of temperature non-uniformities is the shape of the pockets within the wafer carrier. Generally, pocket shapes form a circular shape in the surface of the wafer carrier. As the wafer carrier rotates, the wafers are subject to substantial centripetal force at their outermost edge (i.e., the furthermost edge from the axis of rotation), causing the wafer to press against the interior wall of the respective pocket in the wafer carrier. Under this condition, there is intimate contact between these outer edges of the wafers and the pocket edge. The increased heat conduction to these outer-most portions of the wafers results in more temperature non-uniformity, further aggravating the problems described above.

Efforts have been made to minimize the temperature non-uniformities by increasing the gap between the wafer's edge and the interior wall of the pocket, including designing a wafer that is flat on a portion of the edge. This flat portion of the wafer creates a gap and decreases the points of contact with the interior wall of the pocket, thereby mitigating temperature non-uniformities. Other factors affecting the heating uniformity throughout the wafers held by the wafer carrier include the heat transfer and emissivity properties of the wafer carrier, combined with the layout of the wafer pockets.

With the temperature-uniformity needs in mind, another desirable property for wafer carriers is to increase the throughput of the CVD process. The role of the wafer carrier in increasing process throughout is holding a larger quantity of individual wafers. Providing a wafer carrier layout with more wafers affects the thermal model. For instance, the portions of the wafer carrier near the edges tend to be at a lower temperature than other portions due to radiative heat loss from the wafer carrier edges.

Accordingly, a practical solution is needed for wafer carriers in which temperature uniformity and mechanical stresses in high-density layouts are addressed.

### BRIEF SUMMARY

A wafer carrier includes an arrangement of pockets and a thermal cover made of a plurality of cover segments. The arrangements described herein facilitate heat uniformity on the wafer carrier and/or enhance throughput of the CVD process.

### BRIEF DESCRIPTION OF THE DRAWINGS

The invention may be more completely understood in consideration of the following detailed description of various embodiments of the invention in connection with the accompanying drawings, in which:

FIG. 1 is a schematic view of a MOCVD process chamber, according to an embodiment.

FIG. 2 is a perspective view of a wafer carrier with thermal cover according to an embodiment.

FIG. 3 is a perspective view of the wafer carrier with thermal cover.

FIG. 4A is a top plan view of the wafer carrier.

FIG. 4B is a top plan view of a component plate of the wafer carrier.

FIG. 4C is a top perspective view of a wafer carrier embodiment having only radially inner staples.

FIG. 5 is a detailed view of a platform corresponding to section 5 of FIG. 4B.

FIG. 6 is a detailed perspective view of the edge of a platform including radially inner and outer pedestals.

FIG. 7 is a cross-sectional view of a platform and a pair of radially inner and outer pedestals.

FIGS. 8A and 8B are a bottom plan view and a bottom perspective view, respectively, of wafer carriers with thermal covers.

FIGS. 9A and 9B are top and bottom perspective views, respectively, of one of the plurality of cover segments that make up the thermal cover.

FIG. 10 is a perspective view of an alternative embodiment of a wafer carrier with thermal cover.

FIG. 11 is an exploded view of the wafer carrier with thermal cover of FIG. 10.

FIG. 12 is a perspective view of a thermal cover segment corresponding to the wafer carrier with thermal cover of FIG. 10.

FIG. 13 is a perspective view of a locking bar corresponding to the wafer carrier with thermal cover of FIG. 10.

FIG. 14 is a perspective view of an alternative embodiment of a wafer carrier with thermal cover.

FIG. 15 is an exploded view of the wafer carrier with thermal cover of FIG. 14.

FIG. 16 is a perspective view of a thermal cover segment corresponding to the wafer carrier with thermal cover of FIG. 14.

FIG. 17 is a perspective view of an alternative embodiment of a wafer carrier with thermal cover.

FIG. 18 is an exploded view of the wafer carrier with thermal cover of FIG. 17.

FIG. 19 is a perspective view of a thermal cover segment corresponding to the wafer carrier with thermal cover of FIG. 17.

FIG. 20 is a cut out of a perspective view of an alternative embodiment of a wafer carrier with thermal cover.

FIG. 21 is a perspective view of an alternative embodiment of a wafer carrier with thermal cover.

FIG. 22 is a perspective view of an alternative embodiment of a wafer carrier with thermal cover.

### DETAILED DESCRIPTION

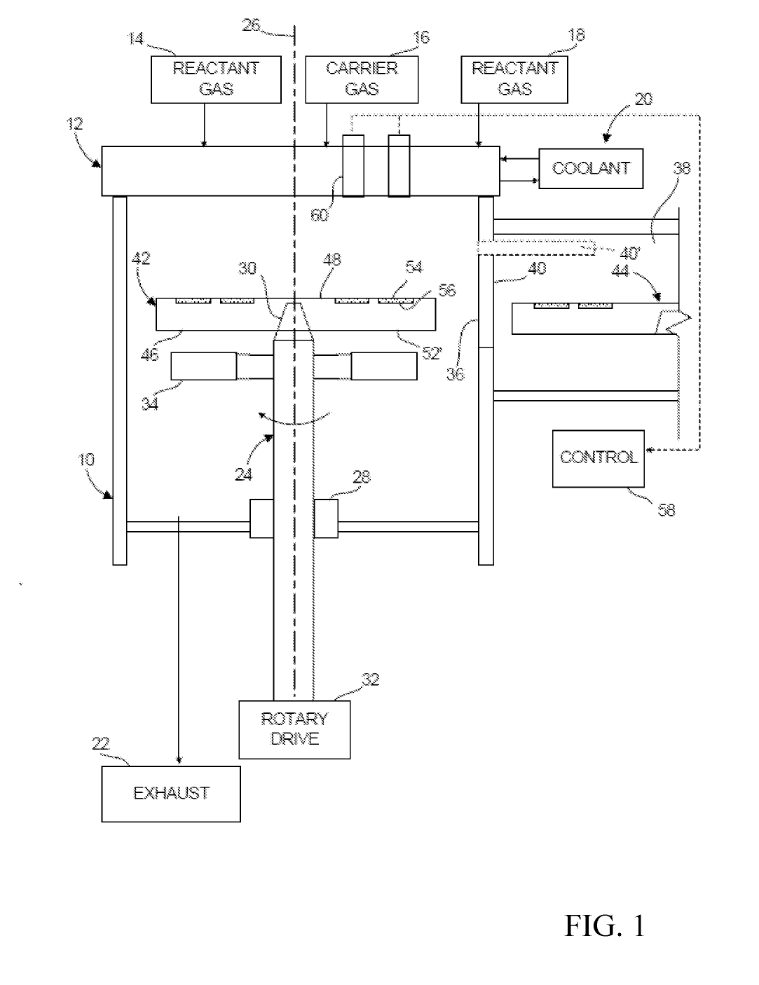

FIG. 1 illustrates a chemical vapor deposition apparatus in accordance with one embodiment of the invention. The embodiment shown in FIG. 1 is just one version of a chemical vapor deposition system, and others, such as the PROPEL™ system that is sold by VEECO®, described in more detail in U.S. Patent Application Pub. No. 2015/0075431, which is incorporated by reference herein in its entirety.

As shown in FIG. 1, reaction chamber 10 defines a process environment space. Gas distribution device 12 is arranged at one end of the chamber. The end having gas distribution device 12 is referred to herein as the “top” end of reaction chamber 10. This end of the chamber typically, but not necessarily, is disposed at the top of the chamber in the normal gravitational frame of reference. Thus, the downward direction as used herein refers to the direction away from gas distribution device 12; whereas the upward direction refers to the direction within the chamber, toward gas distribution device 12, regardless of whether these directions are aligned with the gravitational upward and downward directions. Similarly, the “top” and “bottom” surfaces of elements are described herein with reference to the frame of reference of reaction chamber 10 and gas distribution device 12.

Gas distribution device 12 is connected to sources 14, 16, and 18 for supplying process gases to be used in the wafer treatment process, such as a carrier gas and reactant gases, such as a metalorganic compound and a source of a group V metal. Gas distribution device 12 is arranged to receive the various gases and direct a flow of process gases generally in the downward direction. Gas distribution device 12 desirably is also connected to coolant system 20 arranged to circulate a liquid through gas distribution device 12 so as to maintain the temperature of the gas distribution device at a desired temperature during operation. A similar coolant arrangement (not shown) can be provided for cooling the walls of reaction chamber 10. Reaction chamber 10 is also equipped with exhaust system 22 arranged to remove spent gases from the interior of the chamber 10 through ports (not shown) at or near the bottom of the chamber so as to permit continuous flow of gas in the downward direction from gas distribution device 12.

Spindle 24 is arranged within the chamber so that the central axis 26 of spindle 24 extends in the upward and downward directions. Spindle 24 is mounted to the chamber by a conventional rotary pass-through device 28 incorporating bearings and seals (not shown) so that spindle 24 can rotate about central axis 26, while maintaining a seal between spindle 24 and the wall of reaction chamber 10. The spindle has fitting 30 at its top end, i.e., at the end of the spindle closest to gas distribution device 12. As further discussed below, fitting 30 is an example of a wafer carrier retention mechanism adapted to releasably engage a wafer carrier. In the particular embodiment depicted, fitting 30 is a generally frustoconical element tapering toward the top end of the spindle and terminating at a flat top surface. A frustoconical element is an element having the shape of a frustum of a cone. Spindle 24 is connected to rotary drive mechanism 32 such as an electric motor drive, which is arranged to rotate spindle 24 about central axis 26.

Fitting 30 can also be any number of other configurations. For example, a spindle 24 having an end shaped as a square or rounded-square, a series of posts, an oval or other rounded shape having an aspect ratio other than 1:1, triangle, could be inserted into a matching fitting 30. Various other keyed, splined, or interlocking arrangements between spindle 24 and fitting 30 can be used that maintain rotational engagement between those components and prevent undesirable slipping. In embodiments, keyed, splined, or interlocking arrangements can be used that maintain desired levels of rotational engagement between fitting 30 and spindle 24 despite expected amounts of thermal expansion or contraction of either component.

Heating element 34 is mounted within the chamber and surrounds spindle 24 below fitting 30. Reaction chamber 10 is also provided with entry opening 36 leading to antechamber 38, and door 40 for closing and opening the entry opening. Door 40 is depicted only schematically in FIG. 1, and is shown as movable between the closed position shown in solid lines, in which the door isolates the interior of reaction chamber 10 from antechamber 38, and an open position shown in broken lines at 40′. The door 40 is equipped with an appropriate control and actuation mechanism for moving it between the open position and closed positions. In one embodiment, the door may include a shutter movable in the upward and downward directions as disclosed, for example, in U.S. Pat. No. 7,276,124, the disclosure of which is hereby incorporated by reference herein. The apparatus depicted in FIG. 1 may further include a loading mechanism (not shown) capable of moving a wafer carrier from the antechamber 38 into the chamber and engaging the wafer carrier with spindle 24 in the operative condition, and also capable of moving a wafer carrier off of spindle 24 and into antechamber 38.

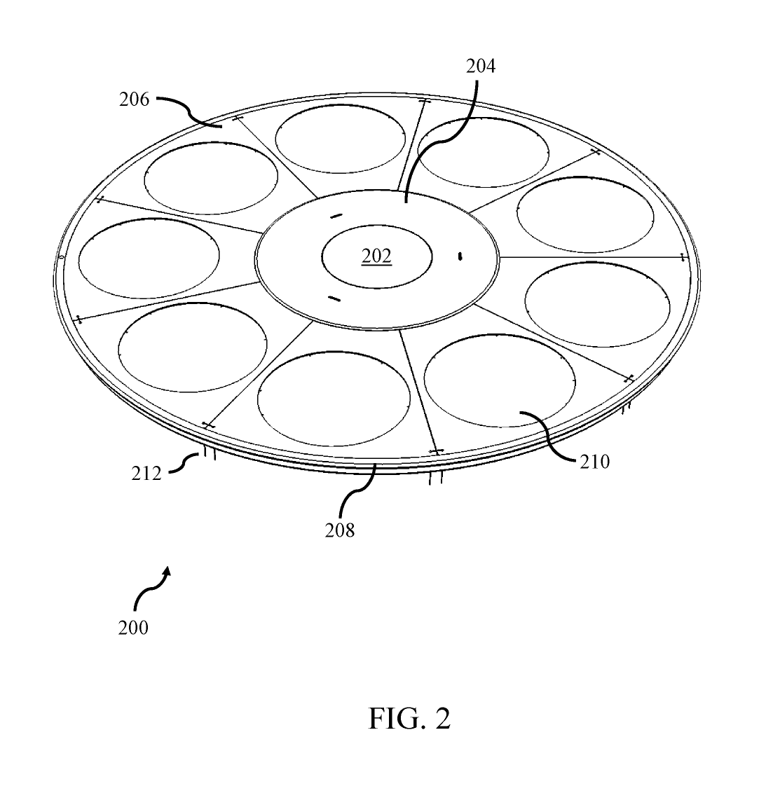

The apparatus also includes a plurality of wafer carriers. In the operating condition shown in FIG. 1, a first wafer carrier 42 is disposed inside reaction chamber 10 in an operative position, whereas a second wafer carrier 44 is disposed within antechamber 38. Each wafer carrier includes body 46 which is substantially in the form of a circular disc having a central axis (See FIG. 2). Body 46 is formed symmetrically about an axis. In the operative position, the axis of the wafer carrier body is coincident with central axis 26 of spindle 24. Body 46 may be formed as a single piece or as a composite of plural pieces. For example, as disclosed in U.S. Patent Application Pub. No. 20090155028, the disclosure of which is hereby incorporated by reference herein, the wafer carrier body may include a hub defining a small region of the body surrounding the central axis and a larger portion defining the remainder of the disc-like body. Body 46 is desirably formed from materials which do not contaminate the process and which can withstand the temperatures encountered in the process. For example, the larger portion of the disc may be formed largely or entirely from materials such as graphite, silicon carbide, or other refractory materials. Body 46 generally has a planar top surface 48 and a bottom surface 52 extending generally parallel to one another and generally perpendicular to the central axis of the disc. Body 46 also has one, or a plurality, of wafer-holding features adapted to hold a plurality of wafers.

In operation, wafer 54, such as a disc-like wafer formed from sapphire, silicon carbide, or other crystalline substrate, is disposed within each pocket 56 of each wafer carrier. Typically, wafer 54 has a thickness which is small in comparison to the dimensions of its major surfaces. For example, a circular wafer of about 2 inches (50 mm) in diameter or a circular wafer of about 4 inches (100 mm) in diameter or a circular wafer of about 150 mm (6 inches) may be used with a thickness of about 770 μm or less. As illustrated in FIG. 1, wafer 54 is disposed with a top surface facing upwardly, so that the top surface is exposed at the top of the wafer carrier. In addition, other sized wafers such as squares, hexagonals, and the like are also contemplated.

In a typical MOCVD process, wafer carrier 42 with wafers loaded thereon is loaded from antechamber 38 into reaction chamber 10 and placed in the operative position shown in FIG. 1. In this condition, the top surfaces of the wafers face upwardly, towards gas distribution device 12. Heating element 34 is actuated, and rotary drive mechanism 32 operates to turn spindle 24 and hence wafer carrier 42 around axis 26. Typically, spindle 24 is rotated at a rotational speed from about 50-1500 revolutions per minute. Process gas supply units 14, 16, and 18 are actuated to supply gases through gas distribution device 12. The gases pass downwardly toward wafer carrier 42, over top surface 48 of wafer carrier 42 and wafers 54, and downwardly around the periphery of the wafer carrier to the outlet and to exhaust system 22. Thus, the top surface of the wafer carrier and the top surfaces of wafer 54 are exposed to a process gas including a mixture of the various gases supplied by the various process gas supply units. Most typically, the process gas at the top surface is predominantly composed of the carrier gas supplied by carrier gas supply unit 16. In a typical chemical vapor deposition process, the carrier gas may be nitrogen, and hence the process gas at the top surface of the wafer carrier is predominantly composed of nitrogen with some amount of the reactive gas components.

Heating elements 34 transfer heat to the bottom surface 52 of wafer carrier 42, principally by radiant heat transfer. The heat applied to bottom surface 52 of wafer carrier 42 flows upwardly through the body 46 of the wafer carrier to the top surface 48 of the wafer carrier. Heat passing upwardly through the body also passes upwardly through gaps to the bottom surface of each wafer, and upwardly through the wafer to the top surface of wafer 54. Heat is radiated from the top surface 48 of wafer carrier 42 and from the top surfaces of the wafer to the colder elements of the process chamber as, for example, to the walls of the process chamber and to gas distribution device 12. Heat is also transferred from the top surface 48 of wafer carrier 42 and the top surfaces of the wafers to the process gas passing over these surfaces.

In the embodiment depicted, the system includes a number of features designed to assess uniformity of heating of the surfaces of each wafer 54. In this embodiment, temperature profiling system 58 receives temperature information that can include a temperature and temperature monitoring positional information from temperature monitor 60. In addition, temperature profiling system 58 receives wafer carrier positional information, which in one embodiment can come from rotary drive mechanism 32. With this information, temperature profiling system 58 constructs a temperature profile of the pockets 56 on wafer carrier 42. The temperature profile represents a thermal distribution on the surface of each of the pockets 56 or wafers 54 contained therein.

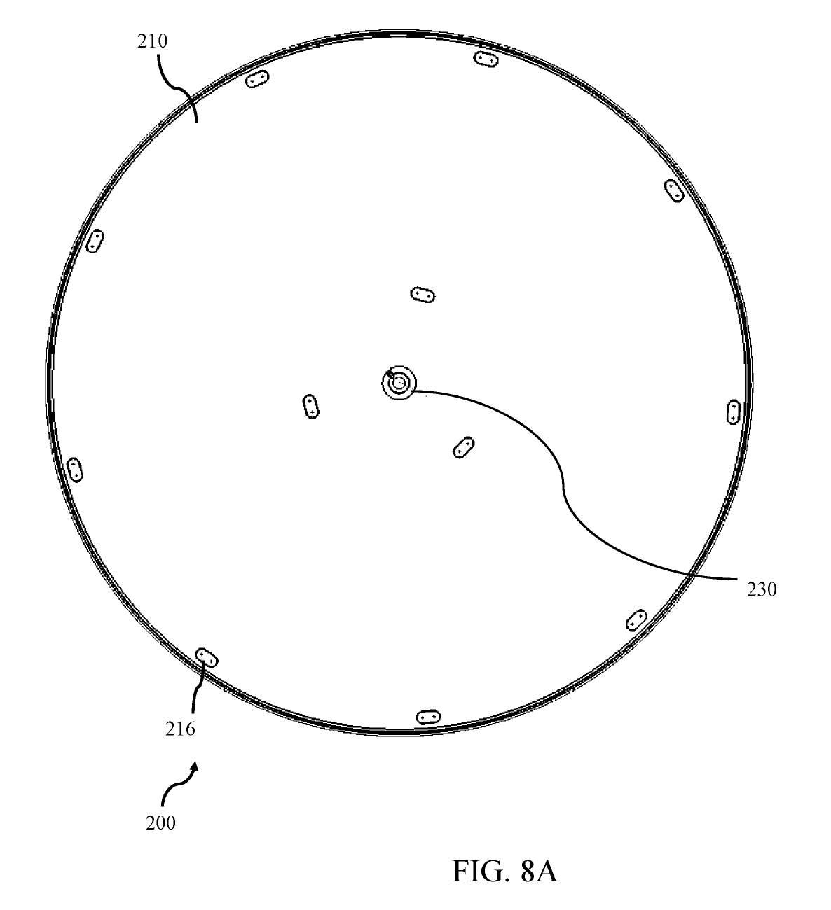

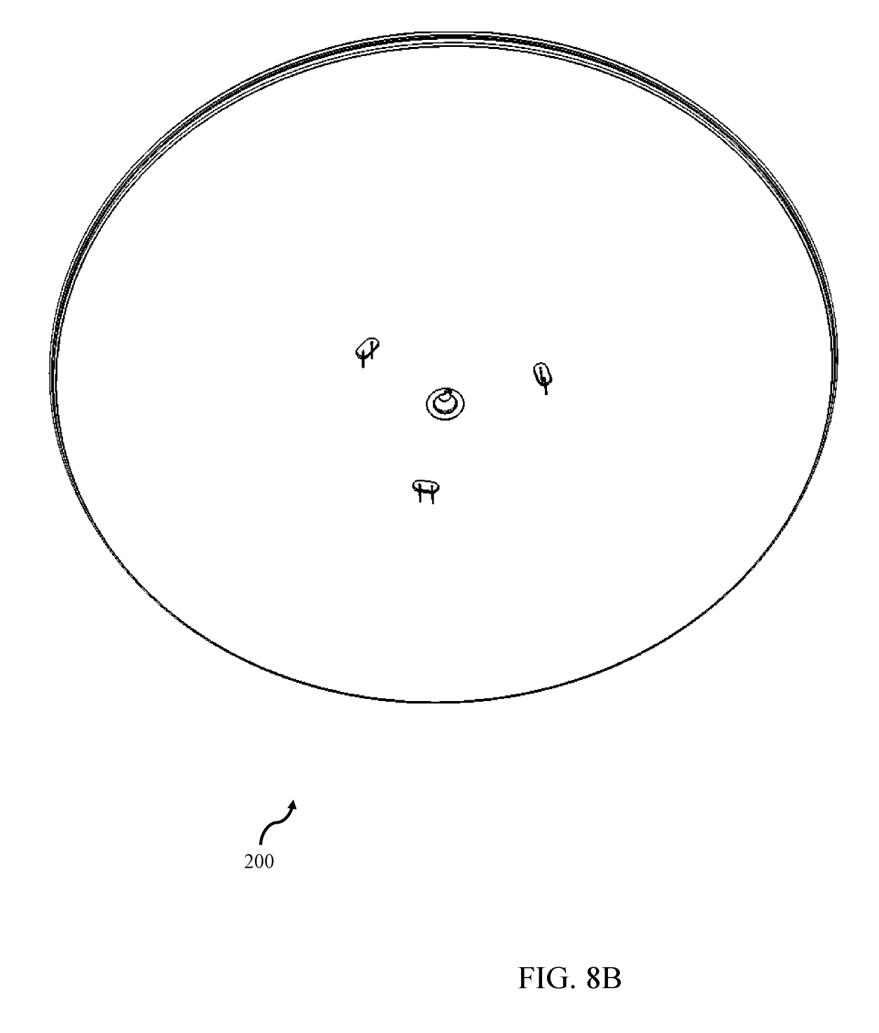

FIG. 2 is a perspective view of a wafer carrier 200, according to an embodiment. The embodiment shown in FIG. 2 includes a inner portion 202 configured to receive a spindle (e.g., spindle 24 as shown in FIG. 1). In the perspective view of FIG. 2, the fitting (e.g., fitting 30 of FIG. 1) is not visible. Rather, an example fitting is shown in FIG. 8.

Radially outward from inner portion 202 is disc 204 that has an inner circumference extending around inner portion 202. Radially outward from disc 204 are a plurality of cover segments 206. The plurality of cover segments 206, taken in combination, define an inner circumference extending around disc 204. Lip 208 is arranged radially outward from plurality of cover segments 206, and defines an inner circumference extending around the plurality of cover segments 206. Each of these interfaces can include a “knife edge”, overhang, or bevel such that lip 208 prevents radially outward or upward movement of cover segments 206, and disc 204 prevents upward movement of segments 206 at their radially inner edges.

Each of the plurality of cover segments 206 defines a substantially circular aperture that exposes a portion of plate 210. In the embodiment shown in FIG. 2, the portions of plate 210 that are exposed are circular, and correspond to pockets for epitaxial growth of a wafer.

Staples 212 are arranged to hold each of the plurality of cover segments 206 to the plate 210. Staples 212 also hold disc 204 to plate 210. Staples 212 are shown in exploded view along with one of the plurality of cover segments 206 and disc 204 to depict holes 214 that are configured to receive staples 212. Each staple 212 includes a back-span and one or more projections configured to extend through the plate 210. In alternative embodiments, staples 212 could have two projections (as shown in the Figures), or more than two projections (for example, three projections that couple three cover segments). The number and arrangement of projections attached to the back-span of staples 212 can be determined based on the particular orientation of cover segments 206 and expected stresses thereon during the MOCVD process. Staples 212 can also be centrifugally balanced, in embodiments, such that rotation of plate 210 is not significantly imbalanced by the mass of staples 212 during rotation at expected speeds of several thousand rotations per minute.

In alternative embodiments, fasteners other than staples could be used. For example, in an embodiment a central screw and nut could be used to affix cover segments 206 to plate 210, as could a clamp or any of a number of other fasteners. Such fasteners can be made of materials that correspond in thermal expansion coefficient to the remainder of wafer carrier 200, but with sufficient mechanical strength to prevent movement during rotation, such as silicon carbide, tungsten, or molybdenum.

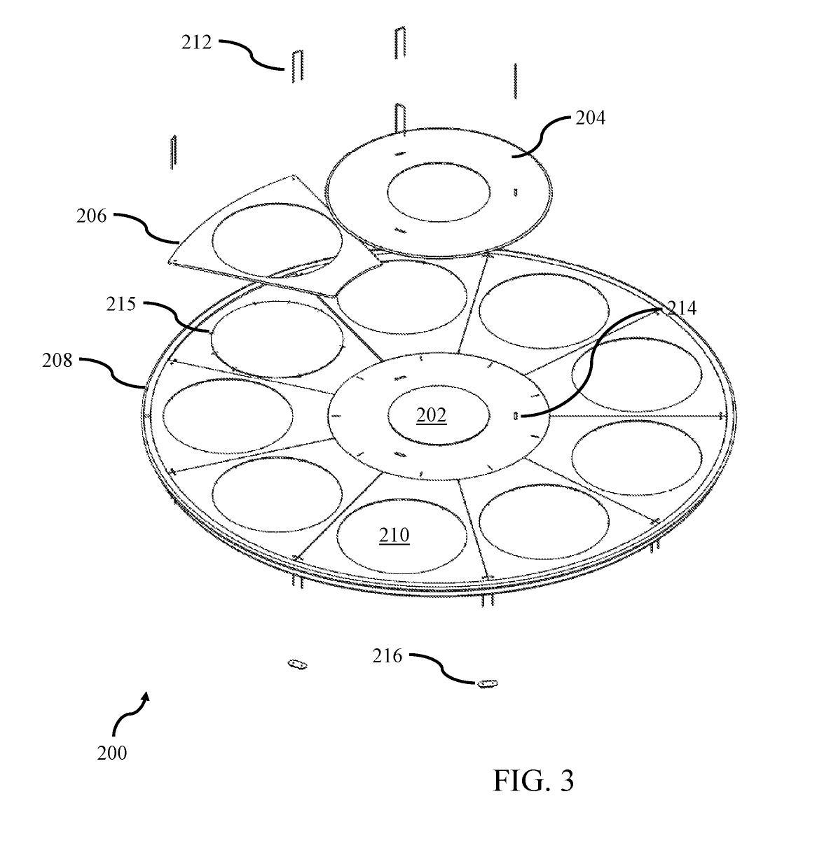

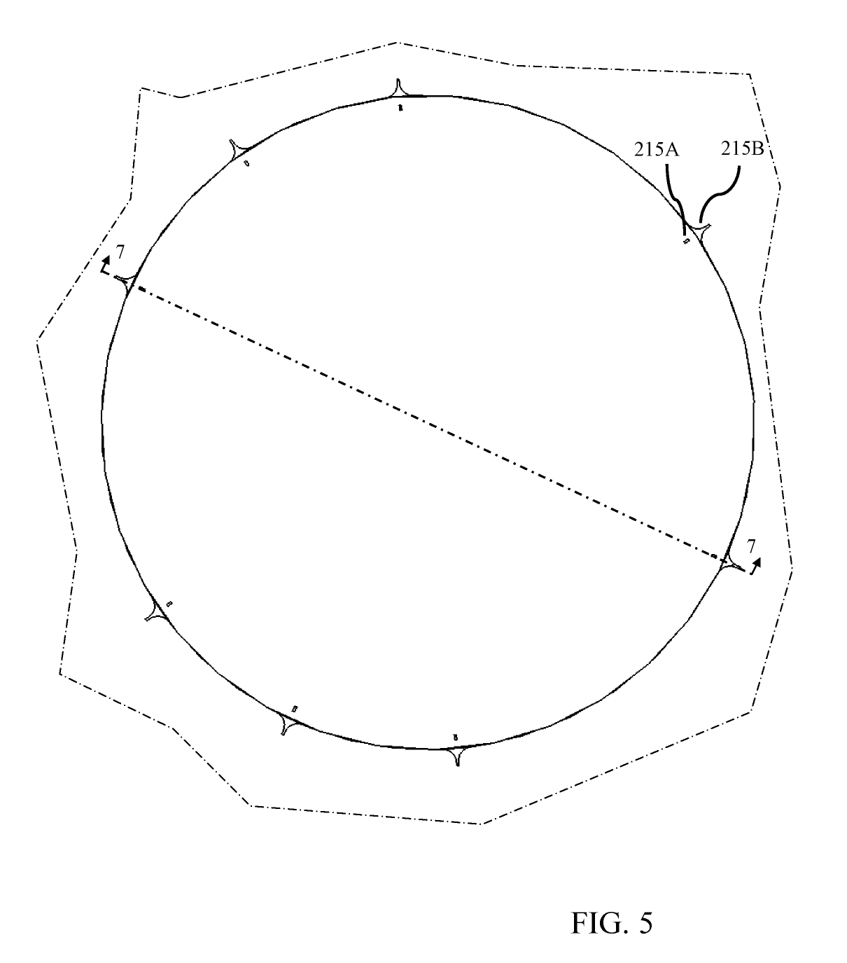

FIG. 3 is a partially exploded view of wafer carrier 200. In the exploded view shown in FIG. 3, the portion of plate 210 arranged underneath disc 204 in the view of FIG. 2 is shown. Pedestals 215 are arranged in a circular pattern on plate 210 to support the radially outer portion of disc 204, and pedestals 215 are grouped in pairs of corresponding wafer pedestals (which are radially inner with respect to each pocket) and cover pedestals (which are radially outer with respect to each pocket), as shown in more detail with respect to FIGS. 5-7, below. FIG. 3 further depicts washers 216 that are configured to hold staples 212.

Likewise, in the partially exploded view of wafer carrier 200, the portion of plate 210 arranged underneath one of the segments 206 is shown. Pedestals 215 are also arranged along the circular border of the aperture formed by the segments 206. As shown in FIGS. 5-7, the pedestals around the apertures of segments 206 can be arranged in radially inner and outer pairs that have different heights from one another.

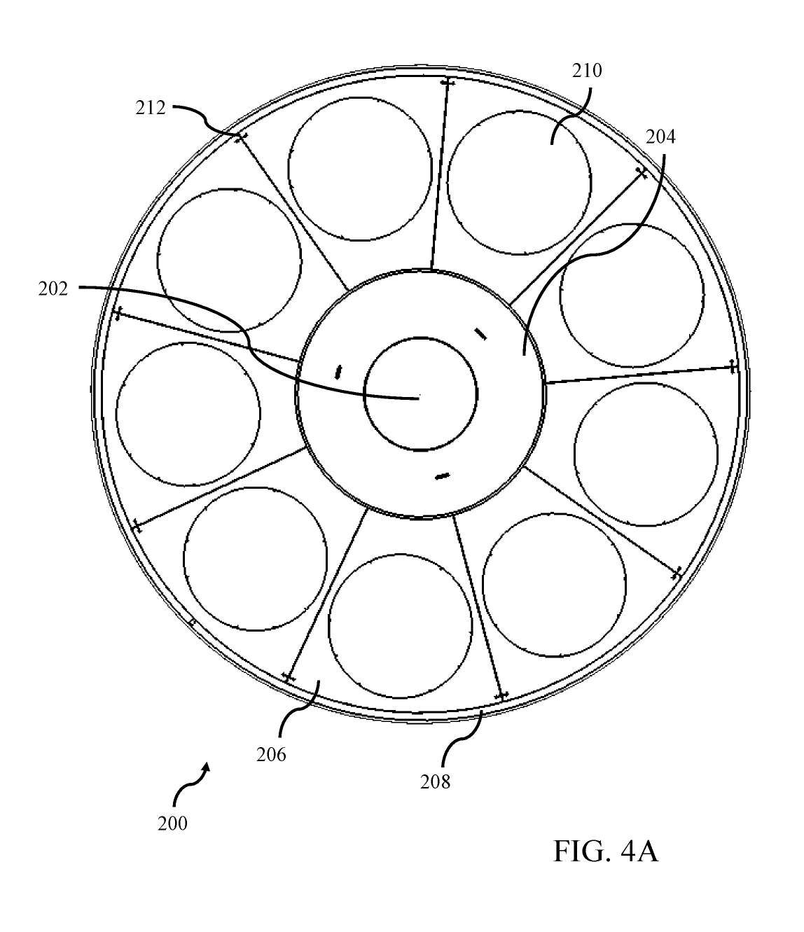

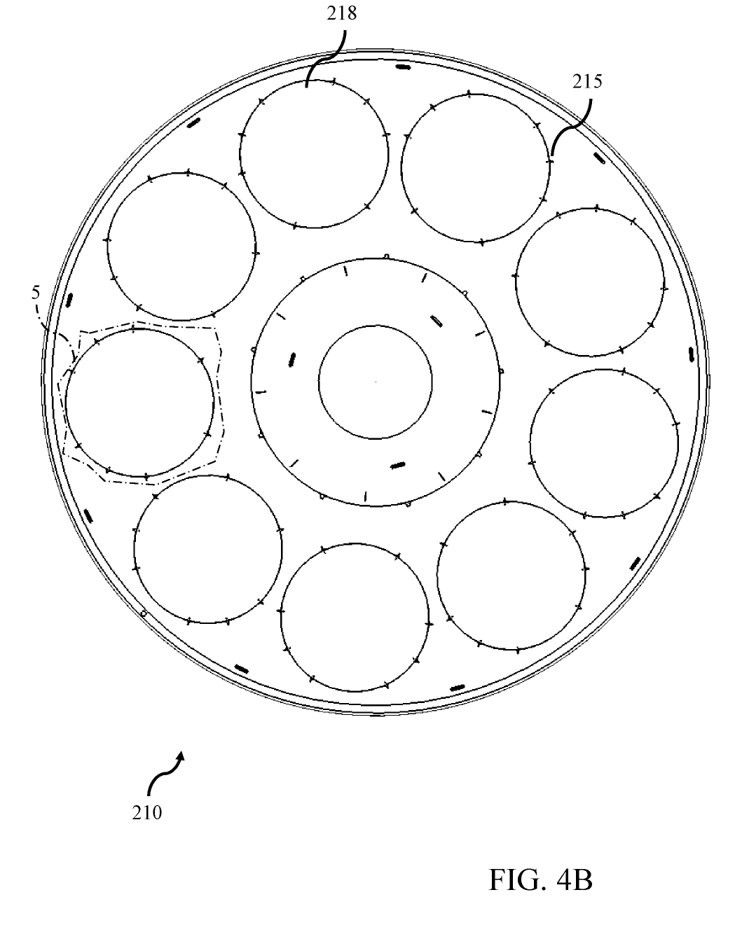

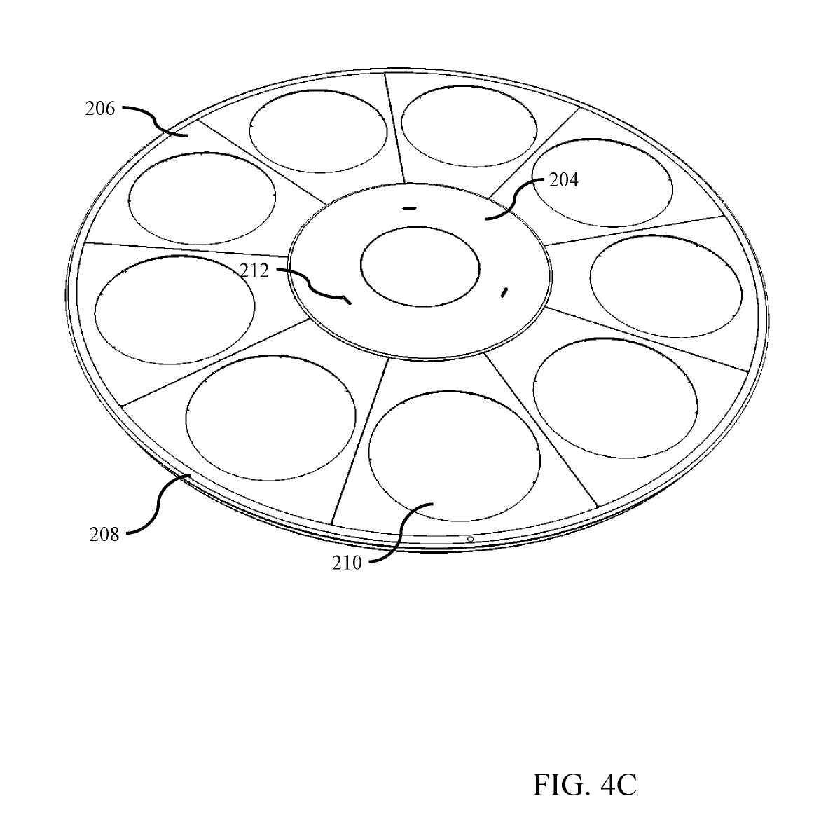

FIG. 4A is a top view of the wafer carrier 200. FIG. 4B is a top view of plate 210. FIG. 4B depicts section 5, which is illustrated in more detail in FIG. 5. FIG. 4C is a top perspective view of an alternative embodiment in which only radially inner staples 212 are used. Radially inner staples 212 hold disc 204 to plate 210, and disc 204 includes an overhang or similar fastening mechanism to hold the radially inner portions of cover segments 206. Lip 208 likewise contains an overhang or other fastening mechanism to hold the radially outer edge of cover segments 206. In this way cover segments 206 can be held to plate 210 without requiring additional staples 212. The overhang holds the radially outer edges of the plurality of covers 206 to constrain their movement in the outward and upward directions, while permitting radial and lateral movement to account for differential thermal expansion. In alternative embodiments, relatively more or fewer staples 212 could be used, based on the combination of fastening mechanisms provided in the design to prevent radially outward or longitudinally upward movement of the plurality of cover segments 206 with respect to plate 210.

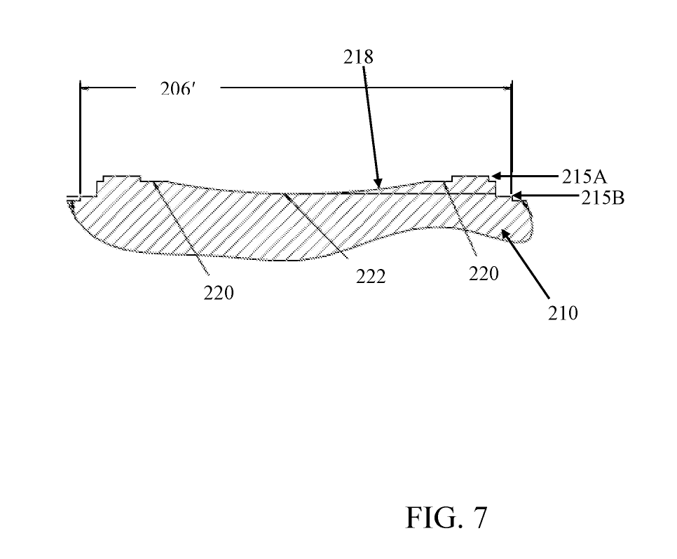

FIG. 5 is an enlarged view of section 5 depicted in FIG. 4B. Section 5 is an enlarged view of a single pocket (i.e., the portion of plate 210 arranged adjacent to the aperture of one of the sections 206 as described above). In FIG. 5, pedestals 215 are shown in more detail, in particular showing an inner pedestal portion 215A and an outer pedestal portion 215B. FIG. 5 also defines cross-section 7-7, shown in more detail in FIG. 7.

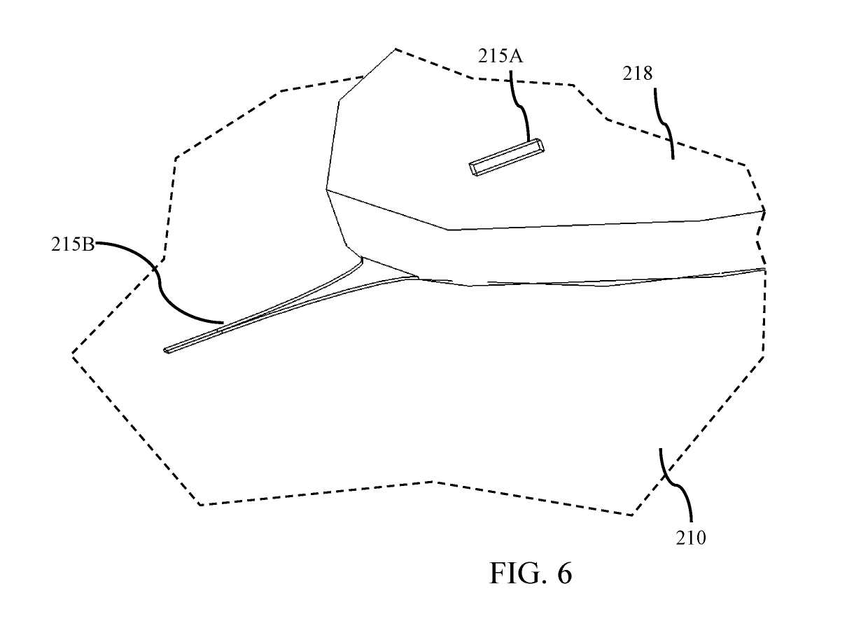

FIG. 6 is a detailed view of pedestal 215, including inner pedestal portion 215A and outer pedestal portion 215B. Inner pedestal portion 215A is configured to hold a wafer or substrate for epitaxial growth, in embodiments. Inner pedestal portion 215A prevents direct thermal contact between plate 210 and that substrate, except at the relatively small upper surface of inner pedestal portion 215A.

Outer pedestal portion 215B, in contrast, is configured to hold segments 206 such that the segments 206 are not in direct thermal contact with plate 210 except at the relatively small upper surface of outer pedestal portion 215B.

In embodiments, wafer carrier 200 is configured such that a wafer within the portion of plate 210 at each pedestal has approximately the same height as a cover segment 206 positioned on radially outer pedestal portions 215B. By modifying the heights of the pedestal portions 214A and 214B, as well as the materials that make up cover portions 206, net vertical thermal conductivity at operational conditions of between about 700° C. and about 900° C. can be achieved that is consistent as between portions of the wafer carrier 200 that are undergoing epitaxial growth and those that are not. In alternative embodiments, different heights of pedestals 214A and 214B can be used that will achieve beneficial thermal conductivity patterns under these and other operational conditions and temperatures. This desired net thermal conductivity effect can be, for example, consistent thermal conductivity between the wafers and the thermal covers, or consistent thermal conductivity across the entire plate 210, for example.

As shown in FIG. 6, inner pedestal portion 215A is arranged on a platform 218. Platform 218 extends from the top surface of plate 210.

FIG. 7 is a cross-sectional view of the portion of plate 210 indicated in FIG. 5 by cross-sectional line 7-7. The cross-section depicted in FIG. 7 shows concave platform 219, with less recessed portion 220 arranged adjacent radially inner pedestal portion 215A, and more recessed portion 222 arranged therebetween. Width 206′ corresponds to the width of an aperture in segment 206 that can be arranged adjacent to the portion depicted in FIG. 7.

In alternative embodiments the platform profile can have any of a variety of profiles, such as flat, convex, contoured, or textured. Tabs and bow of the pocket can be similar to conventional pockets, but raised from the plate surface rather than sunken into the plate surface based on the thickness of the cover segments 206.

FIG. 8A is a bottom view of wafer carrier 200, according to an embodiment. Washers 216 are arranged along the bottom surface of plate 210 to receive staples 212, as described above. The bottom surface of plate 210 also includes an engagement mechanism 230 for coupling to a spindle or similar structure to drive rotation. Engagement mechanism 230 is similar to fitting 30 of FIG. 1, and can be any of a variety of splines, fasteners, keyed engagement, or other fittings. For example, a spline, keyed structure, set of posts, or other rotationally asymmetric coupling could be used to attach plate 210 to a corresponding driver.

FIG. 8B is a bottom view of an alternative embodiment in which only central staples 212 are used (i.e., the staples 212 that hold disc 204 to plate 210) but not radially outer staples (i.e., the staples 212 that hold cover segments 206 to plate 210 in alternative embodiments).

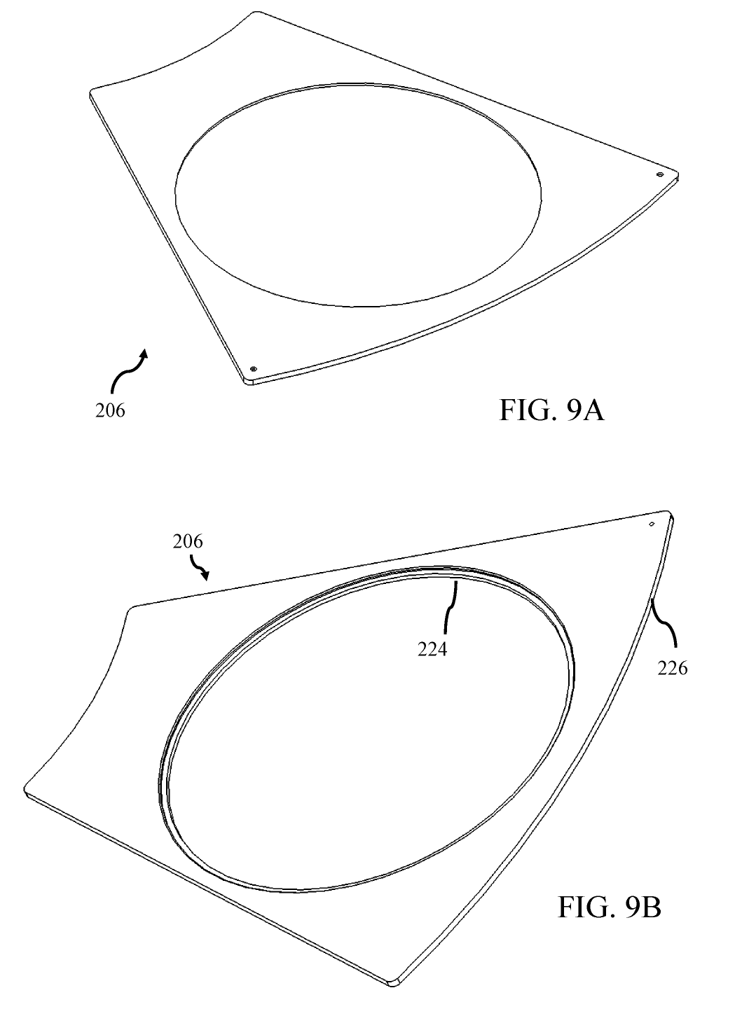

FIGS. 9A and 9B are perspective top and perspective bottom views, respectively, of one of the plurality of cover segments 206. FIG. 9B depicts edge 224 configured to engage with a substrate for growing a wafer in embodiments.

In embodiments, a thickness 226 of each of the plurality of cover segments 206 can be set such that the thickness of the radially outer pedestal 215B in addition to the thickness of the platform 226 is approximately equal to the thickness of the outer edge of the platform 218 plus the thickness of the radially inner pedestals 215A plus the thickness of a desired substrate and wafer (not shown). Thus the thicker the pedestal 218 that is used, the thicker the plurality of cover segments 206 will be. In embodiments, segments 206 can be made of quartz or another material that has thermal transfer characteristics that are similar to a substrate or wafer that is to be grown. In embodiments, segments 206 with different material compositions can be interchanged between uses to match thermal characteristics of a wafer grown epitaxially on platforms 218 or a substrate arranged thereon.

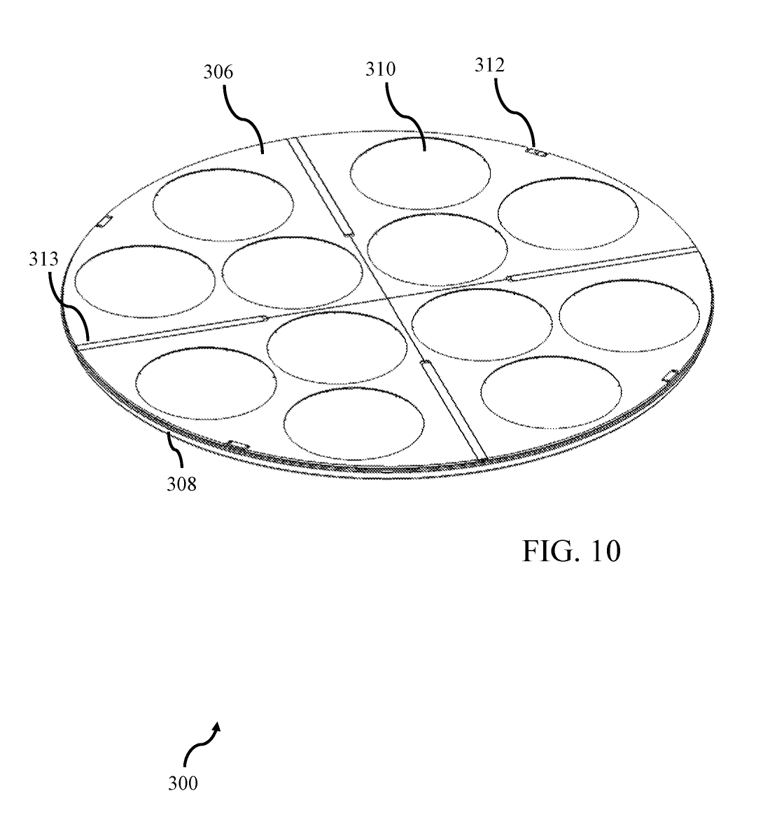

FIG. 10 depicts an alternative embodiment having a unique arrangement of pockets and locking features. In particular, FIG. 10 depicts wafer carrier 300 having four interlocking cover segments 306. Each of the cover segments 306 define three apertures through which plate 310 is accessible. Each of the cover segments 306 mechanically and thermally cover a portion of plate 310 corresponding to π/2 radians of the overall circular top cross-section thereof, extending between the center of plate 310 and the radially outer lip 308.

The embodiment shown in FIG. 10 offers some advantages compared to the embodiment shown in FIG. 2. For example, the number of wafer pockets is increased from nine to twelve, and space in the center of the susceptor is used more efficiently. In alternative embodiments, features from these embodiments could be mixed with one another (such as by adding a central feature, e.g. 202 of FIG. 2, in a design having cover segments arranged in quadrants, e.g., 306 of FIG. 10).

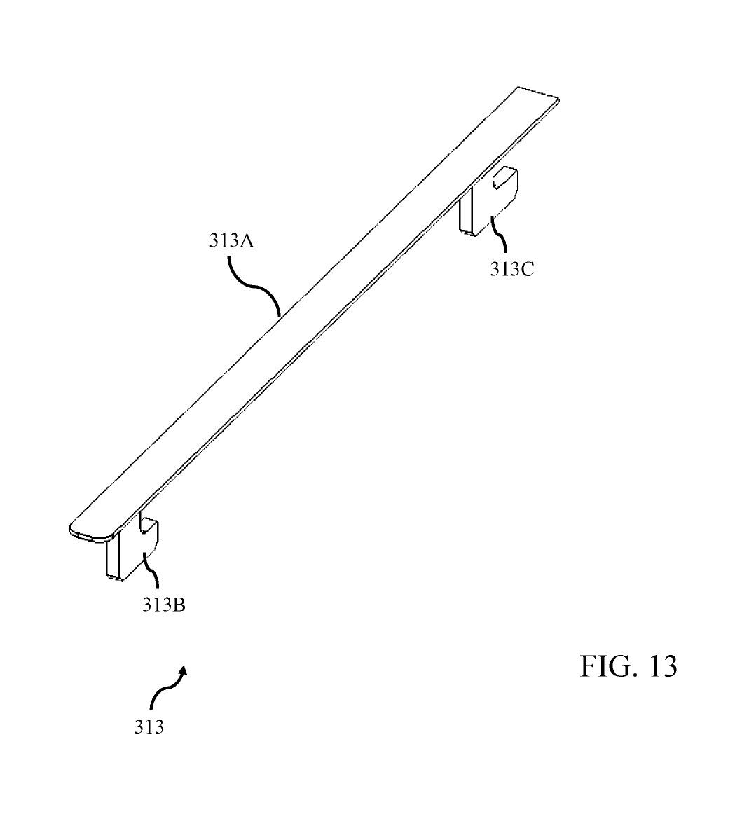

FIG. 10 further shows locking tabs 312 and locking bars 313. These features can retain cover segments 306 during rotation, such as during an MOCVD processing cycle. In embodiments, the use of locking tabs 312 obviates the need for a knife edge or other retaining feature at lip 308. Locking bars 313 are shown in more detail in FIG. 13.

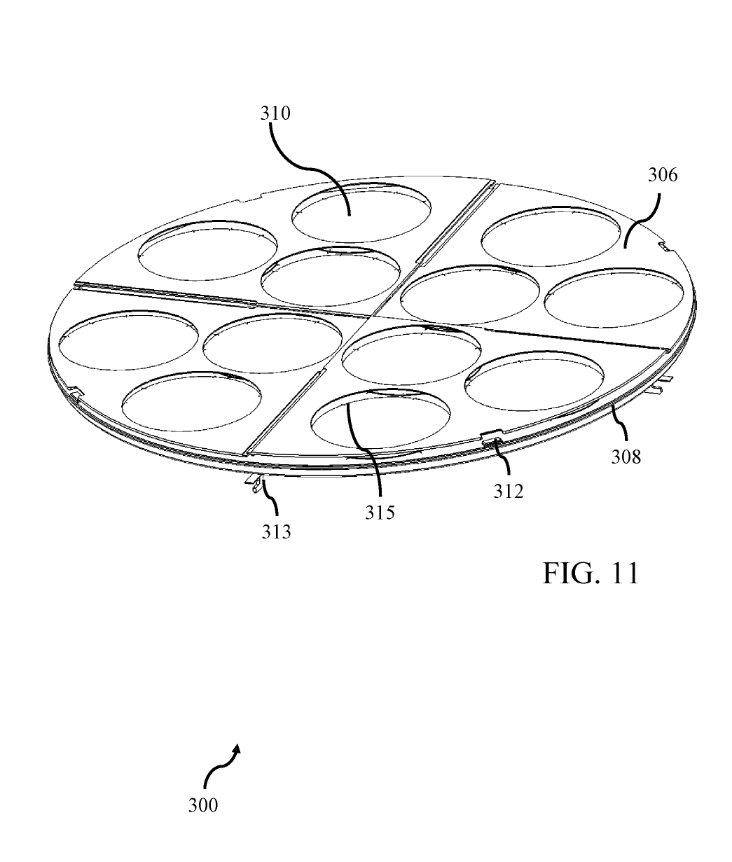

FIG. 11 is an exploded view of the embodiment previously described with respect to FIG. 10. In addition to the cover segments 306, lip 308, plate 310, locking tabs 312, and locking bars 313 described above, pedestals 315 are also shown in FIG. 11. Pedestals 315 are similar to pedestals 215 previously described with respect to FIGS. 4B and 5-7.

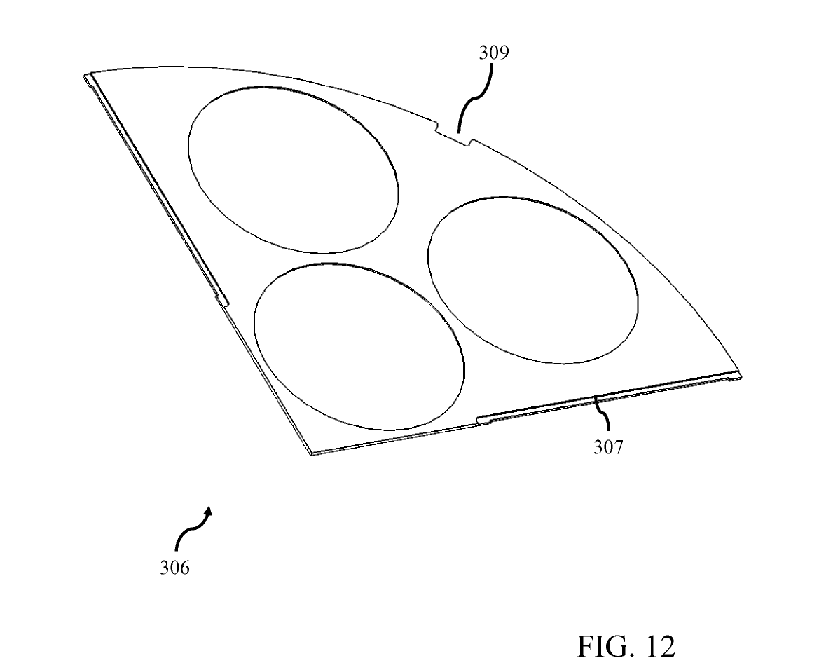

FIG. 12 is a perspective view of cover segment 306, described above with respect to FIGS. 10 and 11. Cover segment 306 is similar to cover segment 206, described above with respect to FIGS. 9A and 9B. Unlike cover segment 206, cover segment 306 includes groove 307 and cutout 309. Groove 307 is configured to mechanically engage with locking bars 313, as shown above with respect to FIG. 10 and described in more detail below with respect to FIG. 13. Cutout 309 is configured to engage with locking tab 312, described above with respect to FIG. 10. In combination, cutout 309 engaged with locking tab 312 and groove 307 engaged with locking bar 313 prevent radial and circumferential movement of cover segment 306 with respect to the underlying plate 310.

FIG. 13 depicts locking bar 313. In the embodiment shown in FIG. 13, locking bar 313 includes a surface portion 313A, a radially inner foot 313B, and a radially outer foot 313C. In alternative embodiments, different numbers of feet could be used, or other coupling or fastening mechanisms could be employed that engage with plate 310. In operation, feet 313B and 313C are latched into corresponding receiving members within plate 310, such that surface portion 313A extends across a portion of a cover segment (306) to retain that cover segment and prevent movement in the circumferential direction.

In alternative embodiments, further features could be added to locking bar 313 that would prevent movement in other directions. For example, surface portion 313A could have burrs or other locking features that prevent radial movement, in addition to circumferential movement, of adjacent cover segments 306 with respect to plate 310.

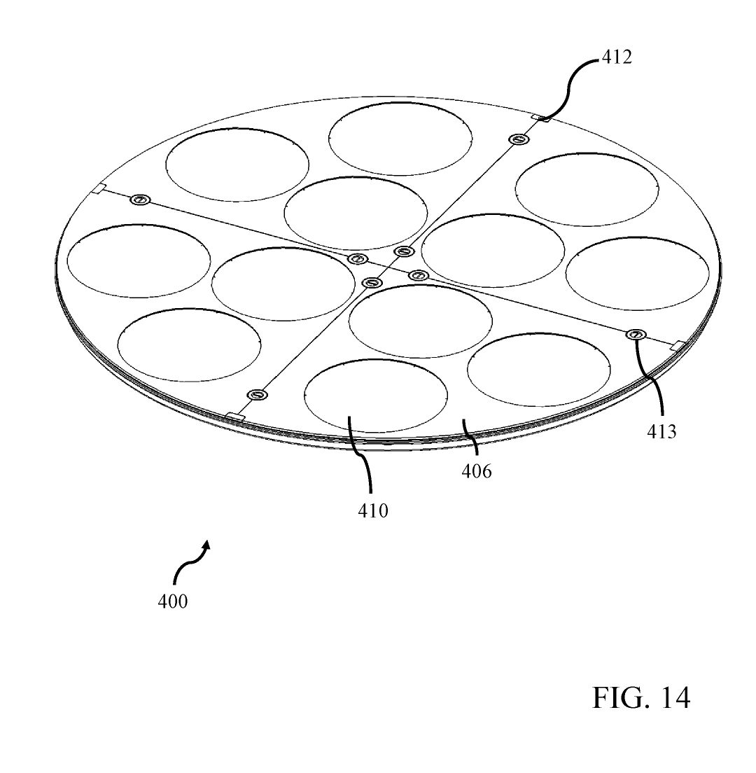

FIG. 14 is another embodiment of a wafer carrier 400, in which the locking mechanism varies from the embodiments described above. In particular, wafer carrier 400 includes four cover segments 406 arranged on a plate 410 to provide thermal insulation similar to that of a wafer (either in thermal transfer coefficient, thickness, or both) and promote uniform heating. Unlike wafer carrier 300, wafer carrier 400 does not include locking bars. In lieu of locking bars, wafer carrier 400 includes a plurality of locking screws 413. Locking screws 413 can engage with a surface of an adjacent cover segment 406 or, in embodiments, a washer, nut, or other connecting member can be arranged therebetween to prevent damage to the cover segments 406. Locking tabs 412 are arranged at the radially outer edge of plate 410 to provide further support to cover segments 406 during rotation of wafer carrier 400.

Although locking screws 413 are used in the embodiment shown in FIG. 14, it should be understood that a variety of alternatives such as clamps, rivets, bolts (e.g., carriage bolts), tie-downs, staples, or other fasteners could be used. Locking screws 413 benefit from relatively high strength, ease of coupling and uncoupling, and low impact on the overall thermal transfer from one side of wafer carrier 400 to the other.

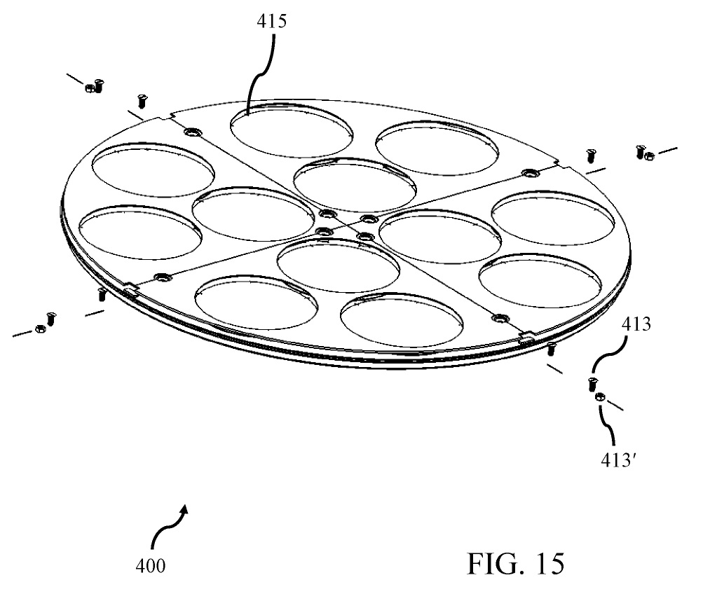

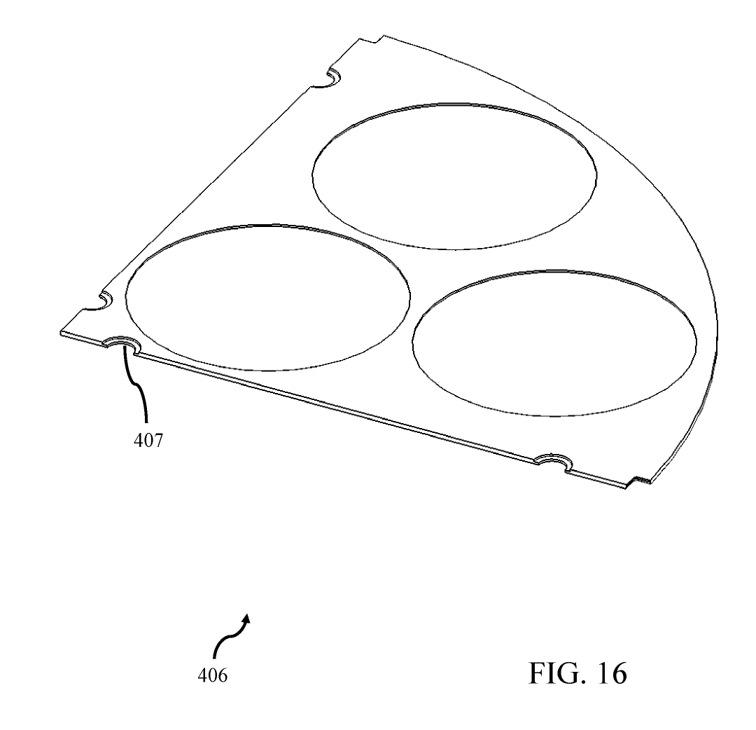

FIG. 15 is an exploded view of wafer carrier 400 described above with respect to FIG. 14. FIG. 15 shows locking screws 413 in more detail, as well as nuts 413′ that are configured to engage with screws 413 to hold cover segments 406 to plate 410. Additionally, the exploded view of FIG. 15 makes pedestals 415 more apparent, which are similar to pedestals 215 described above with respect to FIGS. 4B and 5-7.

FIG. 16 is a perspective view of cover segment 406. Cover segment 406 is similar to cover segment 306 described above with respect to FIG. 12. In lieu of groove 307 and cutout 309, cover segment 406 defines four partial borehoes 407 that are each configured to engage with a screw (413) to hold the cover segment 406 in place during rotation, such as during MOCVD processing.

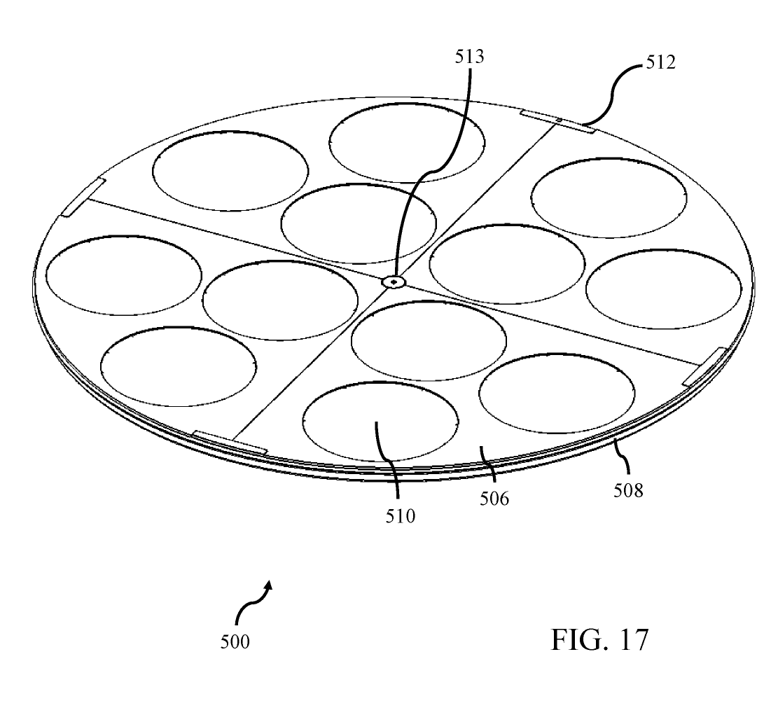

FIG. 17 is another embodiment of a wafer carrier 500, having four thermal cover segments 506 covering platforms 510. Thermal cover segments 506 are held in place at the radially outer edge of wafer carrier 500 by four locking tabs 512. A central fastener 513 holds each of the thermal cover segments 506 at the radially innermost region.

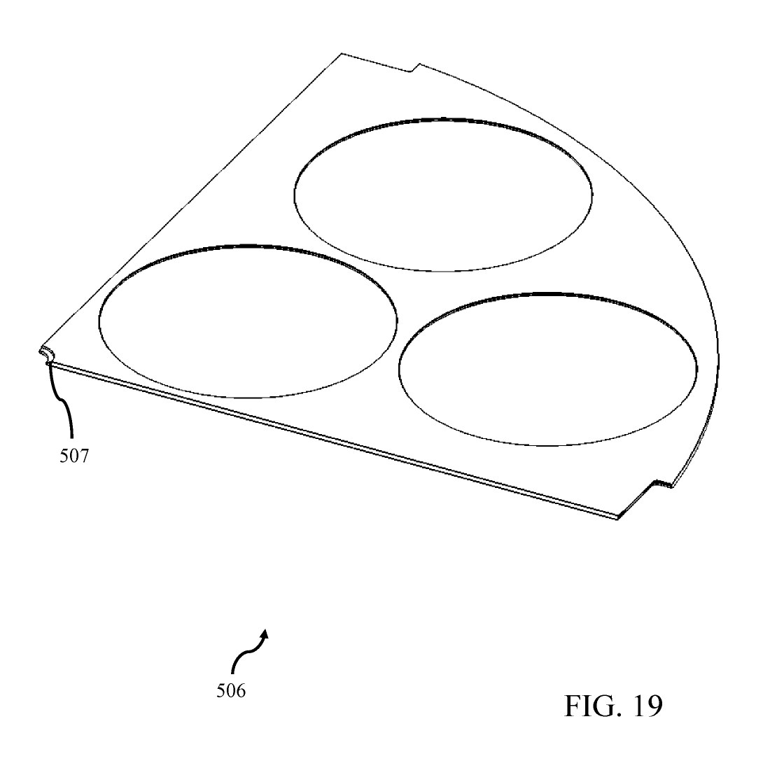

The design illustrated in FIG. 17 is beneficial in that the cover segments 506 are prevented from lifting in the radially innermost region by a single, central fastener 513. Central fastener 513 could be a screw (coupled to a nut positioned on the reverse side of wafer carrier 500 that is not visible in the perspective view of FIG. 17), a clamp, a rivet, or any other type fastener that extends over a portion of the cover segments 506, as shown in more detail below with respect to FIG. 19.

In use, cover segments 506 can be coupled to the remainder of wafer carrier 500 by arranging the cover segments 506 such that the apertures defined therein are each positioned over a platform, as described above in more detail. In the embodiment shown in FIG. 17, this arrangement also results in cover segments 506 mating with locking tabs 512. Next, central fastener 513 engages with wafer carrier 500 to hold cover segments 506. Alternatively, central fastener 513 could be fixed, and locking segments 512 could be movable or removable. In such embodiments, cover segments 506 can be engaged with the central fastener 513 and with the apertures arranged over platforms 510, and subsequently locking features 512 can be engaged to hold cover segments 506.

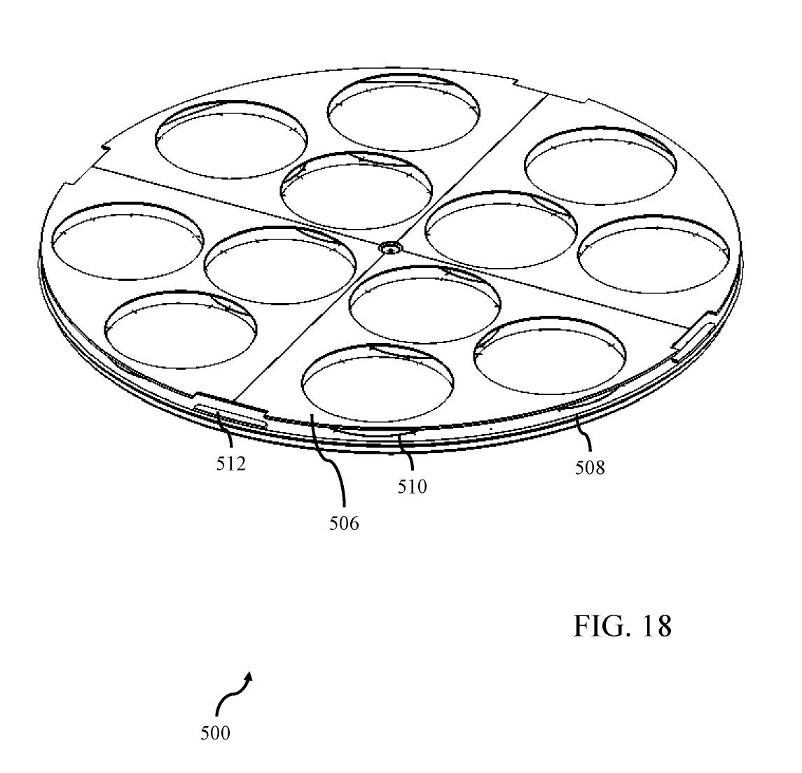

FIG. 18 is an exploded view of wafer carrier 500, depicting the features previously described with respect to FIG. 17 above. In the exploded view of FIG. 18, the sides of platforms 510 are more clearly visible. FIG. 19, in turn, shows shoulders 507 that can engage with adjacent components such as the central fastener 513 or an adjacent cover segment 506.

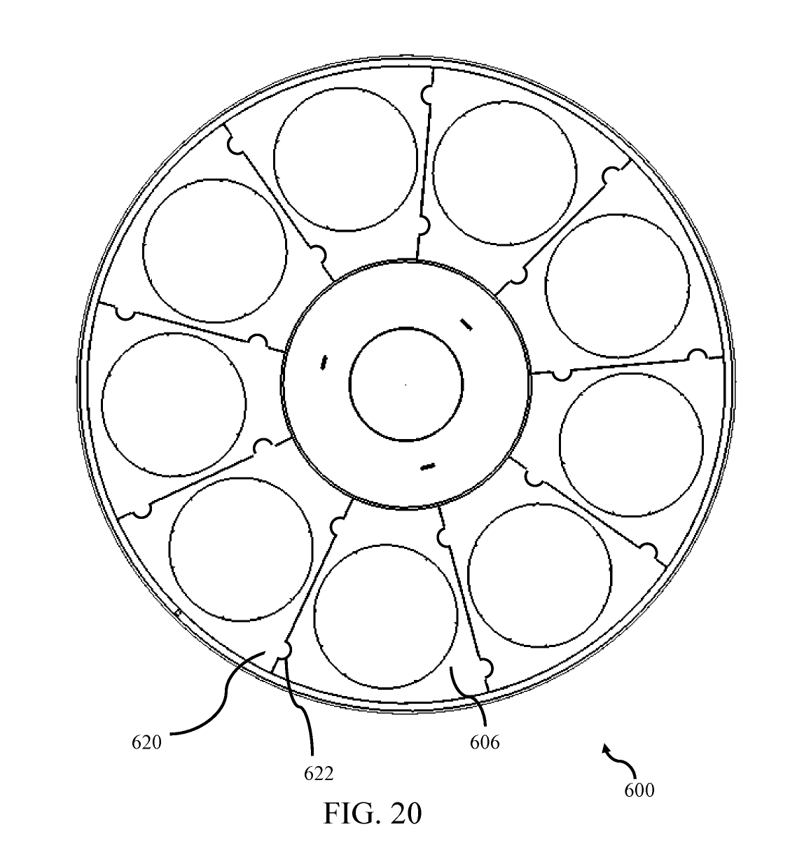

FIG. 20 is another embodiment of wafer carrier 600 in which the walls between each cover segment 606 include movement restricting structures between each cover segment 606. Wafer carrier 600 is similar to wafer carrier 200 but specifically includes male jigsaw structures 620 and female jigsaw structures 622 arranged between each cover segment 606. Specifically, male jigsaw structures 620 interlock with corresponding female jigsaw structures 622 located on adjacent cover segments 606. The engagement between male and female jigsaw structures 620 and 622 serves to restrict radially outward movement of carrier segments 606 as well as movement between carrier segments 606.

Jigsaw structures (620, 622) are relatively easy to fasten against centripetal forces trying to lift and throw the covers (since it is almost centered and quite heavy). Similarly, a jigsaw layout such as the structure shown in FIG. 20 connects the cover segments 5606 laterally and the associated piece-piece friction and interlinked mass is relatively stable. In embodiments, use of a jigsaw structure eliminates or reduces need for fasteners, which can be unwieldy for cleaning and disassembly.

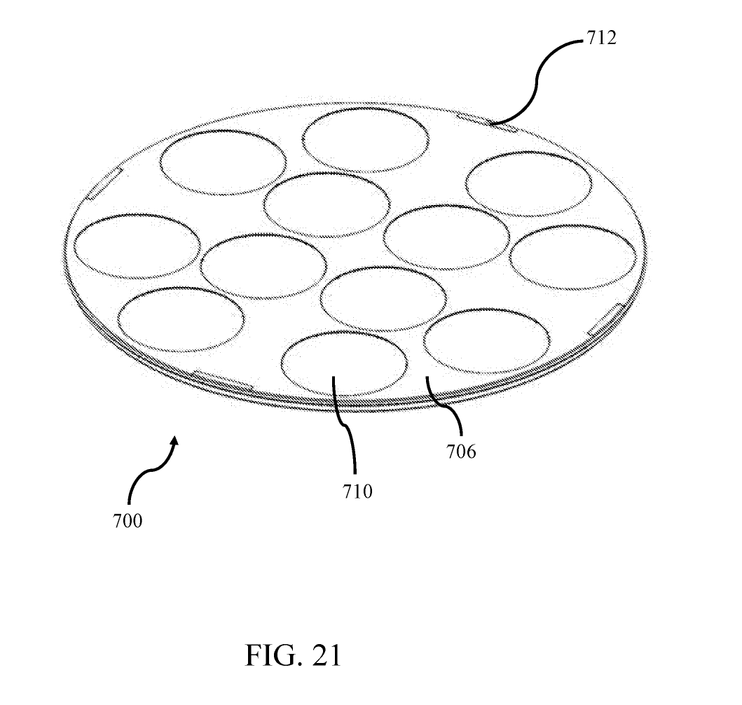

FIG. 21 is another embodiment of a wafer carrier 700, in which the number of cover segments varies from the previously described embodiments. In particular, wafer carrier 700 includes a monolithic cover segment 706 arranged on a plate 710 to provide thermal insulation similar to that of a wafer (either in thermal transfer coefficient, thickness, or both) and promote uniform heating. Unlike previously described embodiments, monolithic cover segment 706 requires no inter-cover segment locking devices as monolithic cover segment 706 is a unitary component. Locking tabs 712 are arranged radially at the outer edge of plate 710 to support monolithic cover segments 706 during rotation of wafer carrier 700.

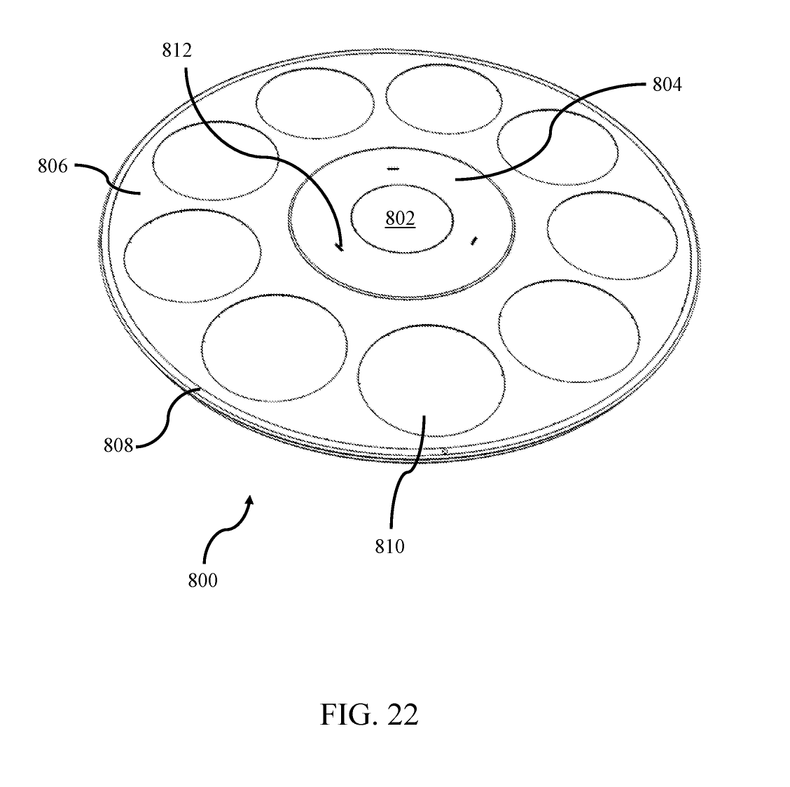

FIG. 22 is another embodiment of wafer carrier 800 in which the number of cover segments varies from wafer carrier 200. Wafer carrier 800 is similar to wafer carrier 800 in that it includes an inner portion 802 and disc 804, yet it includes a monolithic cover segment 806 instead of a plurality of cover segments 206. Wafer carrier 800 also includes a lip 808, plate 810, and staples 812. Unlike wafer carrier 200, wafer carrier 800 includes monolithic cover segment 806 which requires less staples 812 and other supporting components as monolithic cover segment 806 because of its unitary construction.

In alternative embodiments, various other fasteners could be used in addition to locking bars, nuts, or staples. Furthermore, various alternative arrangements of wafer pockets can be used, such as wafer pocket arrangements that include one ring, two rings, or even many rings of pockets. As described above, pedestals can be incorporated into these designs that result in wafer height at a predetermined relationship with the height of the cover segments. Cover segment material and thickness can likewise be selected so that thermal transmission through the wafer before, during, or at the end of MOCVD is similar to thermal transmission through the cover segments.

As described herein, a wafer carrier configured to be used with a chemical vapor deposition device includes one or more plates having a top surface and a bottom surface arranged opposite one another, a plurality of platforms defined on the top surface of the plate, a plurality of cover segments configured to engage with the top surface of the plate, each of the plurality of cover segments defining at least one aperture corresponding to one of the plurality of platforms. These wafer carriers improve upon conventional systems at least in that, for each platform and a corresponding cover segment, a plurality of radially inner pedestals are arranged on only the platform to support a corresponding substrate, and a plurality of radially outer pedestals arranged on only the top surface and configured to support the corresponding cover segment.

In embodiments, screws, clamps, ties, staples, rivets, or other fasteners could be used to hold the plate to the cover segments. In alternative embodiments each cover segment can define one or more than one aperture, or two cover segments can combine to define an aperture. In some embodiments, there could be only one cover segment that defines all of the apertures. In embodiments, the radially inner pedestals and radially outer pedestals could be arranged differently or have different heights corresponding to any of a number of desired vertical thermal profiles, including thermal profiles in which the wafers are hotter, cooler, or the same temperature as the surrounding thermal cover segments.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

The embodiments are intended to be illustrative and not limiting. Additional embodiments are within the claims. In addition, although aspects of the present invention have been described with reference to particular embodiments, those skilled in the art will recognize that changes can be made in form and detail without departing from the scope of the invention, as defined by the claims.

1. A wafer carrier configured to be used with a chemical vapor deposition device, the wafer carrier comprising:
a plate having a top surface and a bottom surface arranged opposite one another;
a plurality of platforms defined on the top surface of the plate;
one or more cover segments configured to engage with the top surface of the plate, each of the one or more cover segments defining at least one aperture corresponding to one of the plurality of platforms;
the improvement comprising:
for each platform and a corresponding cover segment:
a plurality of radially inner pedestals arranged on only the platform to support a corresponding substrate, and
a plurality of radially outer pedestals arranged on only the top surface and configured to support the corresponding cover segment.

2. The wafer carrier of claim 1, wherein the plurality of platforms have a profile selected from flat, concave, bowed, contoured, or textured.

3. The wafer carrier of claim 1, wherein the thickness of the radially outer pedestal in addition to the thickness of the platform is approximately equal to the thickness of an outer edge of the platform plus the thickness of the radially inner pedestals plus the thickness of a desired substrate plus the thickness of a desired epitaxially-grown wafer.

4. The wafer carrier of claim 1, further comprising a locking feature arranged on the bottom surface.

5. The wafer carrier of claim 11, wherein the locking feature is arranged at the geometric center of the bottom surface.

6. The wafer carrier of claim 12, wherein the locking feature is selected from the group consisting of a spline, a chuck, or a keyed fitting.

7. The wafer carrier of claim 1, the top surface and the bottom surface each comprising a diameter, and wherein the diameter of the top surface is greater than the diameter of the bottom surface.

8. The wafer carrier of claim 7, wherein a lip is arranged at the diameter of the top surface, and wherein the lip is configured to interlock with the one or more cover segments.

9. The wafer carrier of claim 8 further comprising a disc arranged opposite each of the one or more cover segments from the lip, and wherein the disc is configured to interlock with the one or more cover segments.

10. The wafer carrier of claim 9, wherein the disc is coupled to the plate with staples.

11. The wafer carrier of claim 9, wherein the one or more cover segments is coupled to the plate with a fastener.

12. The wafer carrier of claim 11 wherein each of the fasteners comprises a staple and a washer.

13. The wafer carrier of claim 1, wherein the wafer carrier is configured for use in a metal oxide chemical vapor deposition system.

14. The wafer carrier of claim 1, wherein the radially outer pedestals and the radially inner pedestals are configured to achieve a desired net vertical thermal conductivity effect.

15. The wafer carrier of claim 1, wherein the one or more cover segments is a monolithic cover segment.

16. The wafer carrier of claim 1, wherein the one or more cover segments is a plurality of cover segments.

17. The wafer carrier of claim 16, wherein each of the plurality of cover segments includes one or more male and female jigsaw structures, wherein the male or female jigsaw structures of one cover segment are configured to engage with the male or female jigsaw structures of an adjacent cover segment.
